(19) United States
(12) Patent Application Publication
(10) Pub. No.: US 2026/0082491 A1
(43) Pub. Date: Mar. 19, 2026

(54) SHELF-AUXILIARY STRUCTURE

(71) Applicant: LITE-ON TECHNOLOGY CORPORATION, Taipei (TW)

(72) Inventors: Zheng-Zong CHEN, Taipei (TW); Hung-Chi Hsu, Taipei (TW); Qi-Hong Yang, Taipei (TW)

(21) Appl. No.: 19/299,390

(22) Filed: Aug. 14, 2025

Related U.S. Application Data
(60) Provisional application No. 63/694,937, filed on Sep. 16, 2024.

(30) Foreign Application Priority Data
Mar. 24, 2025 (TW) 114111012

(51) Int. Cl. H05K 5/02; H05K 7/14; H05K 7/18

(52) U.S. Cl. CPC H05K 5/0204; H05K 5/0221; H05K 7/1488; H05K 7/18; H05K 5/023

(57) ABSTRACT

A shelf-auxiliary structure includes: first/second support members, first/second adapters, a first connecting rod, and a first/a second quick-release connection components. The first and the second support members are fixed on an outer frame of a shelf and separated from each other. The first adapter is fixed on the first support member. The second adapter is fixed on the second support. The first connecting rod spans between the first support member and the second support member, and forms a first and a second acute angles with the first and the second support member respectively. The first quick-release connection component is disposed at the first end of the first connecting rod and is detachably connected to the first adapter. The second quick-release connecting component is disposed at the second end of the first connecting rod and is detachably connected to the second adapter.

This application claims the benefit of U.S. provisional application Ser. No. 63/694,937, filed Sep. 16, 2024 and Taiwan application Serial No. 114111012, filed Mar. 24, 2025, the subject matter of which are incorporated herein by reference.

### BACKGROUND OF THE INVENTION

### Field of the Invention

The invention relates in general to a shelf structure, and more particularly to a shelf-auxiliary structure used in a server rack.

### Description of the Related Art

With the development of technology, in order to meet consumer demands for data processing speed, a server architecture composed of multiple circuit boards with electronic components has been developed. Multiple server architectures can be assembled to form a data center. A conventional server architecture is to install several motherboards on a server rack with a shelf structure, and separate it into multiple spaces to load the motherboards and the wires connecting the motherboards.

In order to avoid the risk of damage to the motherboard inside the server rack due to shaking, external collision or earthquake, and how to enhance the shock absorption effect and structural strength of the server rack is an urgent issue to be solved in the art.

### SUMMARY OF THE INVENTION

One embodiment of the present disclosure provides a shelf-auxiliary structure, wherein the shelf-auxiliary structure includes: a first support member, a second support member, a first adapter, a second adapter, a first connecting rod, a first quick-release connection component and a second quick-release connection component. The first support member and the second support member are fixed to an outer frame of a shelf structure and are separated from each other. The first adapter is fixed on the first support member. The second adapter is fixed on the second support member. The first connecting rod spans between the first support member and the second support member, and forms a first acute angle and a second acute angle with the first support member and the second support member respectively. The first quick-release connection component is disposed at the first end of the first connecting rod and is detachably connected to the first adapter. The second quick-release connection component is disposed at the second end of the first connecting rod and is detachably connected to the second adapter.

According to the above embodiments, the present disclosure provides a shelf-auxiliary structure. By fixing the first support member and the second support member on the outer frame of the shelf structure, and connecting the connecting rod between the first support member and the second support member through the first quick-release connection component, the second quick-release connection component, the first adapter and the second adapter, so that the connecting rod forms a first acute angle and a second acute angle with the first support member and the second support member respectively. Thereby, a connecting structure can be formed to strengthen the outer frame of the shelf structure to provide the effect of shock absorption and vibration prevention. In some embodiments, the number of connecting rods can be increased according to the shock absorption requirements. Since the connecting rod can be assembled and disassembled by quick release, and can be interchanged with each other, thus it not only greatly reduces the time and cost for assembling and building the self-auxiliary structures, but also improves the spatial flexibility of the shelf structure.

### BRIEF DESCRIPTION OF THE DRAWINGS

The above and other aspects of the invention will become better understood with regard to the following detailed description of the preferred but non-limiting embodiment(s). The following description is made with reference to the accompanying drawings.

FIG. 1A is a perspective view illustrating a shelf structure with a shelf-auxiliary structure according to one embodiment of the present disclosure;

FIG. 1B is a perspective view illustrating a partially disassembled structure of the shelf structure as depicted in FIG. 1A;

FIG. 2A is a partial enlarged view illustrating a first support member configured in the shelf structure as depicted in FIG. 1A;

FIG. 2B is a partial enlarged view illustrating a second support member configured in the shelf structure as depicted in FIG. 1A;

FIG. 3A is a perspective view illustrating a partial structure of a first adapter according to one embodiment of the present disclosure;

FIG. 3B is a perspective view illustrating a partial structure of a second adapter according to one embodiment of the present disclosure;

FIG. 4A is an enlarged perspective view illustrating a partial structure in an engaged state of the first adapter, a first quick-release connection component and a first end of a first connecting rod, according to one embodiment of the present disclosure;

FIG. 4B is an enlarged perspective view illustrating a partial structure in a disengaged state of the first adapter, the first quick-release connection component and the first end of the first connecting rod, as depicted based on FIG. 4A;

FIG. 5A is an enlarged perspective view illustrating a partially enlarged structure in an engaged state of the second adapter, a second quick-release connection component and a second end of the first connecting rod, according to one embodiment of the present disclosure; and

FIG. 5B is an enlarged perspective view illustrating a partially enlarged structure in a disengaged state of the second adapter, the second quick-release connection component and the second end of the first connecting rod.

### DETAILED DESCRIPTION OF THE INVENTION

The present specification provides a shelf-auxiliary structure to reduce the time and cost for assembling and building the shelves and the self-auxiliary structures and to improve the spatial flexibility of the auxiliary structure. For the object, technical features and advantages of the present invention to be more easily understood by anyone ordinary skilled in the technology field, a number of exemplary embodiments are disclosed below with detailed descriptions and accompanying drawings.

It should be noted that these embodiments are for exemplary and explanatory purposes only, not for limiting the scope of protection of the invention. The invention can be implemented by using other features, elements, methods and parameters. The preferred embodiments are merely for illustrating the technical features of the invention, not for limiting the scope of protection. Anyone skilled in the technology field of the invention will be able to make suitable modifications or changes based on the specification disclosed below without breaching the spirit of the invention. Designations common to the accompanying drawings are used to indicate identical or similar elements.

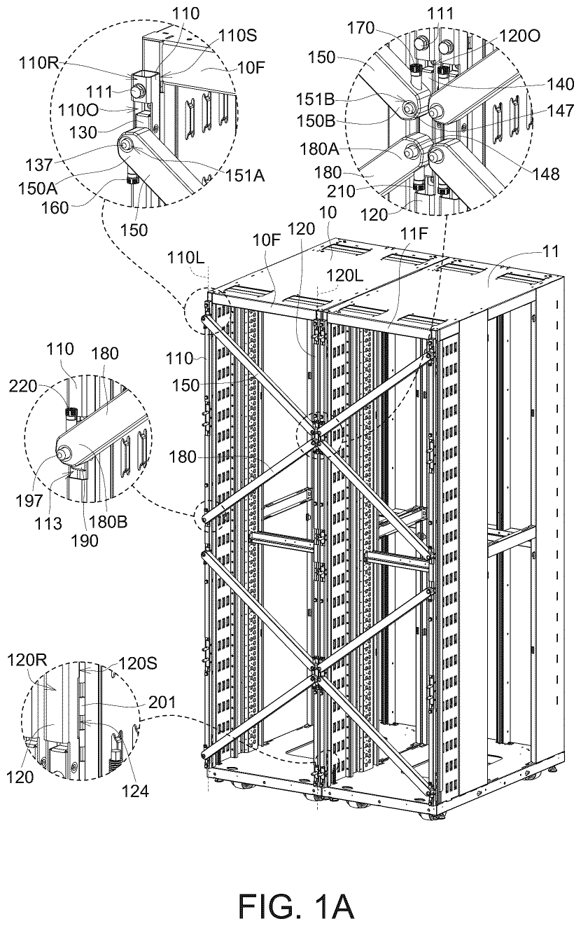

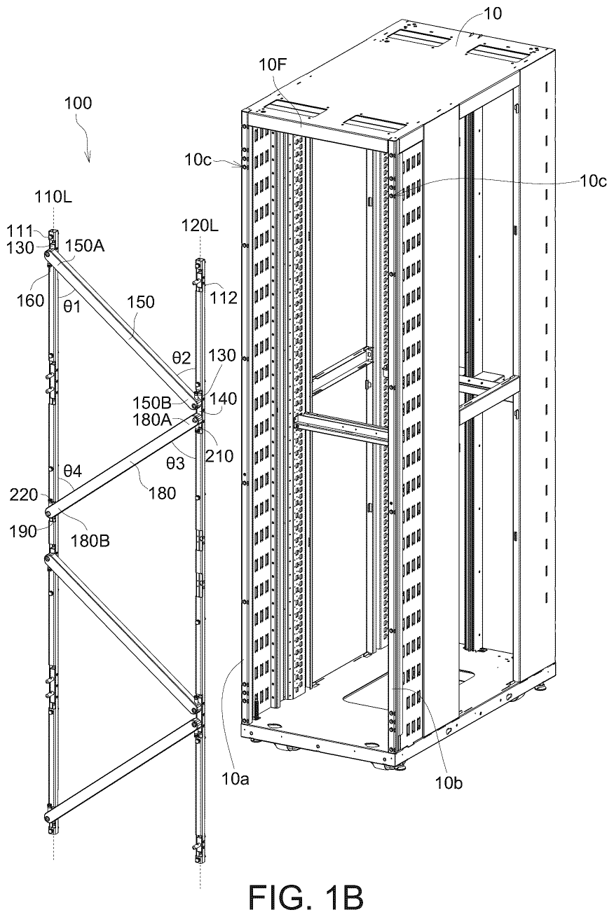

Refer to FIG. 1A and FIG. 1B, FIG. 1A is a perspective view illustrating a shelf structure 10 with a shelf-auxiliary structure 100 according to one embodiment of the present disclosure; and FIG. 1B is a perspective view illustrating a partially disassembled structure of the shelf structure 10 as depicted in FIG. 1A. In some embodiments of the present disclosure, the shelf-auxiliary structure 100 can be applied to the shelf structure 10 having an outer frame 10F. For example, in the present embodiment, the shelf-auxiliary structure 100 can be applied to the shelf structure 10 of a server rack. The shelf-auxiliary structure 100 includes a first support member 110, a second support member 120, a first adapter 130, a second adapter 140, a first connecting rod 150, a first quick-release connection component 160 and a second quick-release connection component 170.

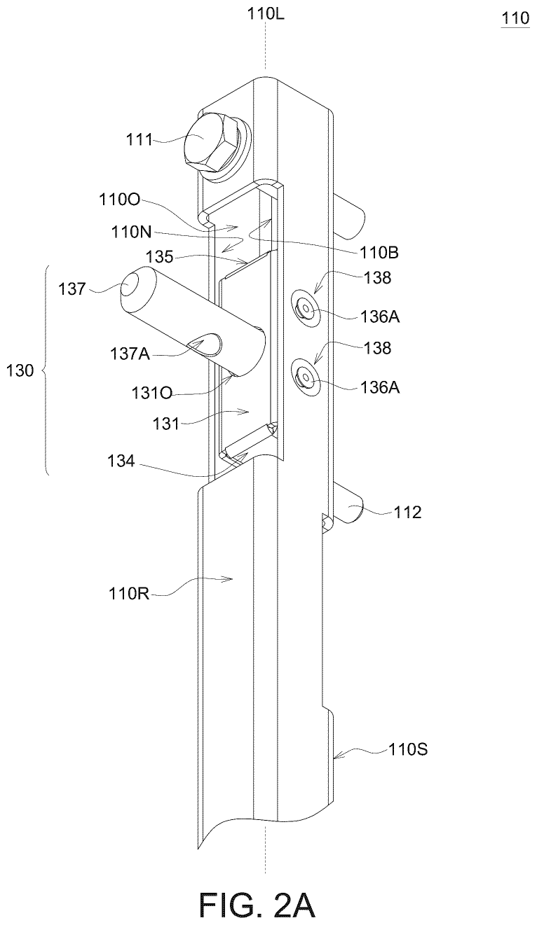

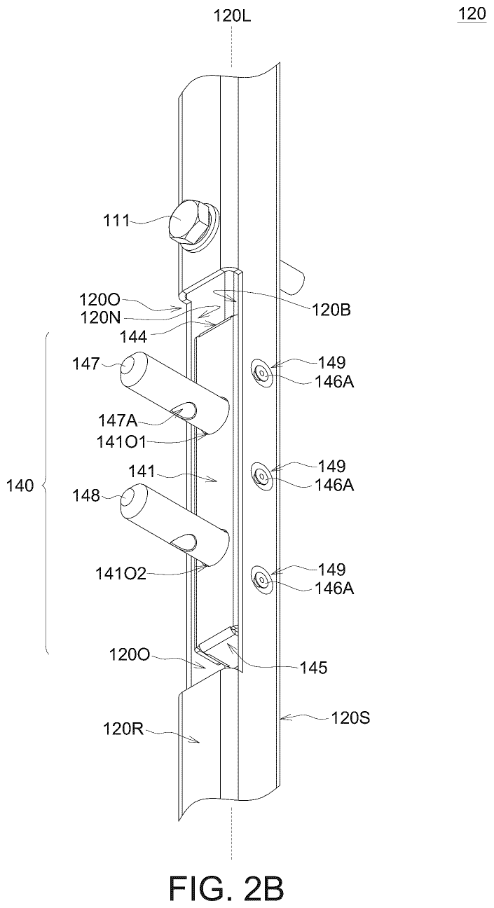

Refer to FIG. 2A and FIG. 2B, FIG. 2A is a partial enlarged view illustrating a first support member 110 configured in the shelf structure 10 as depicted in FIG. 1A; FIG. 2B is a partial enlarged view illustrating a second support member 120 configured in the shelf structure 10 as depicted in FIG. 1A. In some embodiments of the present disclosure, the first support member 110 and the second support member 120 can be a tubular shell structure made of alloy tool steel. The first support member 110 and the second support member 120 are separated from each other and are respectively fixed to the outer frame 10F of the shelf structure 10.

In the present embodiment, the first support member 110 and the second support member 120 may be elongated tubular shell structures having a rectangular cross section. The tubular shell structure of the first support member 110 has a first connecting surface 110S facing the outer frame 10F and a first adapting surface 110R opposite to the first connecting surface 110S. The tubular shell structure of the second support member 120 has a second connecting surface 120S facing the outer frame 10F, and a second adapting surface 120R opposite to the second connecting surface 120S. The first support member 110 is fixed to one side 10a of the outer frame 10F of the shelf structure 10 by at least one (a plurality of) fixing elements, such as bolts 111. The second support member 120 is fixed to the other side 10b of the outer frame 10F of the shelf structure 10 opposite to the side 10a by at least one (a plurality of) fixing elements, such as bolts 111. The first support member 110 has a first longitudinal axis 110L, the second support member 120 has a second longitudinal axis 120L, and the first longitudinal axis 110 is parallel to the second longitudinal axis 120L.

In addition, in some embodiments of the present disclosure, the first support member 110 further includes at least one error-proofing element 112 protruding from the connecting surface 110S and corresponding to at least one positioning element 10c of the outer frame 10F. For example, in the present embodiment, the error-proofing element 112 of the first support member 110 may be a positioning pin, and the positioning element 10c of the outer frame 10F may be a positioning hole recessed on the side 10a of the outer frame 10F. By inserting the positioning pin (the error-proofing element 112) into the positioning hole (positioning element 10c), the first support member 110 can be accurately set at a predetermined position on the side 10a of the outer frame 10F.

Similarly, the second support member 120 may also (optionally) be provided with at least one error-proofing element (not shown) corresponding to a positioning element (not shown) located on the side 10b of the outer frame 10F. It is also worth noting that, in some alternative embodiments, the error-proofing element 112 disposed on the first support member 110 or the second support member 120 may be a positioning hole, and the positioning element 10c disposed on the outer frame 10F may be a positioning pin.

In some embodiments of the present disclosure, the first adapting surface 110R of the first support member 110 has a first opening 110O, and the first adapter 130 can be installed in the first tubular shell structure of the first support member 110 through the first opening 110O. The second adapting surface 120R of the second support member 120 also has a second opening 120O. The second adapter 140 can be installed in the second tubular shell structure of the second support member 120 through the second opening 120O.

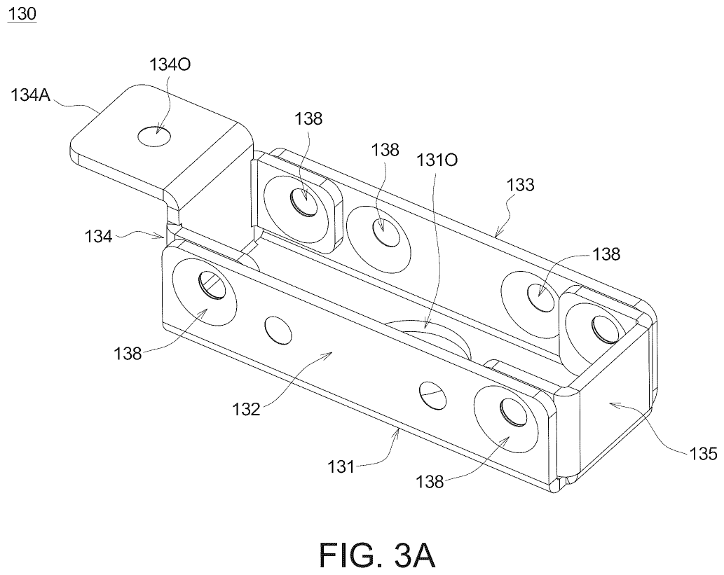

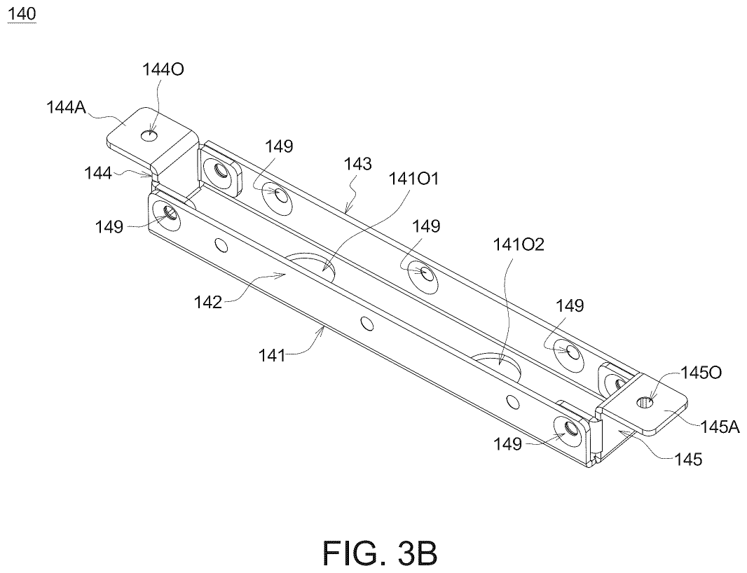

Refer to FIG. 2A and FIG. 3A, FIG. 3A is a perspective view illustrating a partial structure of the first adapter 130 according to one embodiment of the present disclosure. As shown in FIG. 3A, the first adapter 130 is a rectangular shell structure having a size substantially smaller than the first opening 110O of the first support member 110. The first adapter 130 has a first upper plate 131, a first side plate 132, a second side plate 133, a third side plate 134 and a fourth side plate 135. The first side plate 132 and the second side plate 133 are both parallel to the first longitudinal axis 110L of the first tubular shell structure of the first support member 110. The third side plate 134 and the fourth side plate 135 are both perpendicular to the first longitudinal axis 110L.

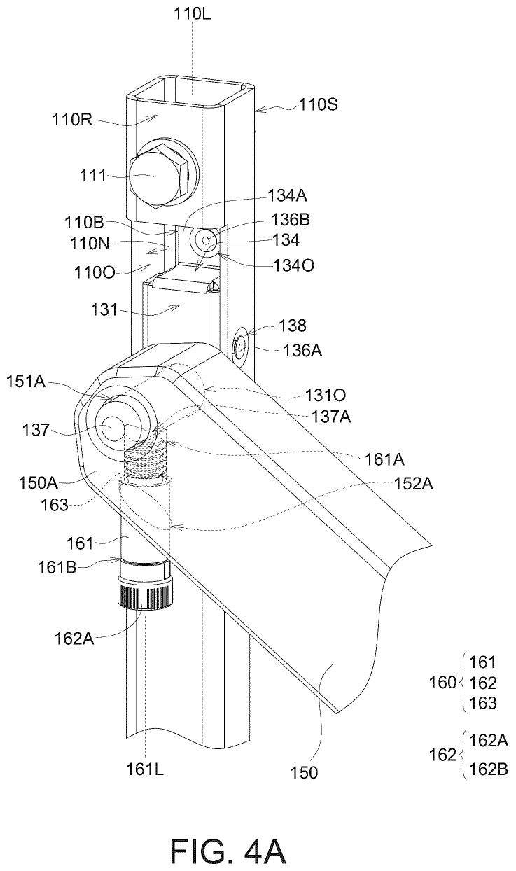

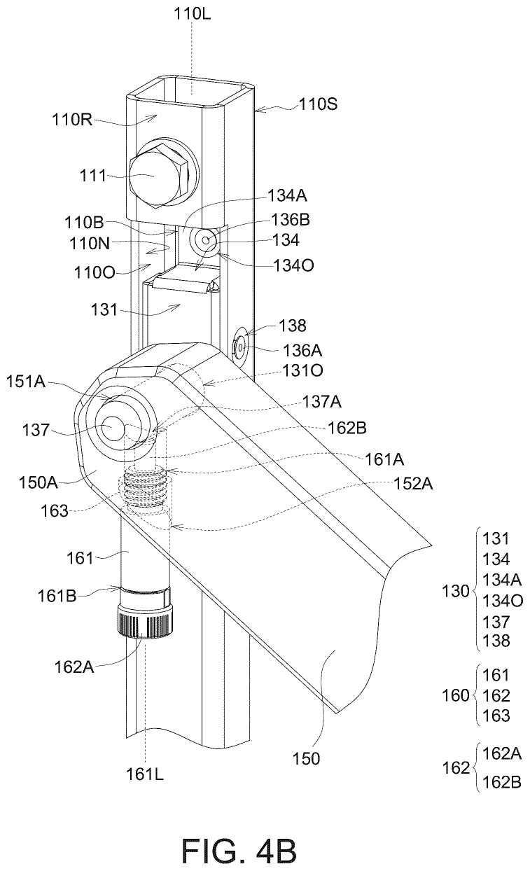

The first side plate 132 and the second side plate 133 respectively have a plurality of through holes 138, and the first adapter 130 is fixed to the inner side walls 110N on both sides of the first tubular shell structure by a plurality of fixing units (e.g., a plurality of rivets 136A) passing through the through holes 138. The third side plate 134 includes a flange 134A extending away from the third side plate 134 in a direction parallel to the first longitudinal axis 110L; and the flange 134A has at least one through hole 134O. The flange 134A of the first adapter 130 is fixed to the inner bottom plate 110B of the first tubular shell structure by a rivet 136B passing through the through hole 134O (See FIG. 4A and FIG. 4B). The first upper plate 131 is parallel to and slightly lower in height than the first adapting surface 110R of the first support member 110, and has a first latch hole 131O penetrating through the first upper plate 131. In addition, the first adapter 130 further includes a first pole 137. One end of the first pole 137 is fixed to the inner bottom plate 110B of the first tubular shell structure, and the other end of the first pole 137 passes through the first latch hole 131O and extends out of the first upper plate 131 and the first opening 110O of the first support member 110.

Refer to FIG. 2B and FIG. 3B, FIG. 3B is a perspective view illustrating a partial structure of a second adapter 140 according to one embodiment of the present disclosure. The second adapter 140 is a rectangular shell structure having a size substantially smaller than the second opening 120O of the second support member 120, and includes a second upper plate 141, a fifth side plate 142, a sixth side plate 143, a seventh side plate 144 and an eighth side plate 145. The fifth side plate 142 and the sixth side plate 143 are both parallel to the second longitudinal axis 120L of the second tubular shell structure of the second support member 120. The seventh side plate 144 and the eighth side plate 145 are both perpendicular to the second longitudinal axis 120L.

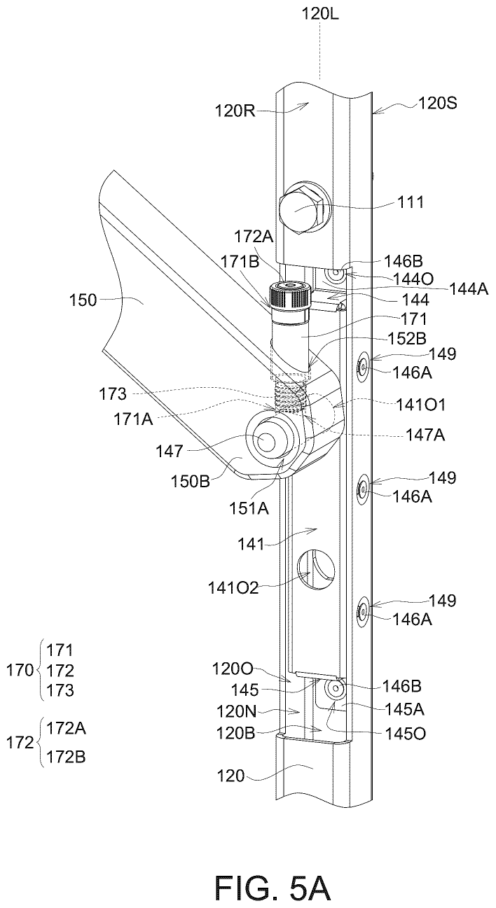

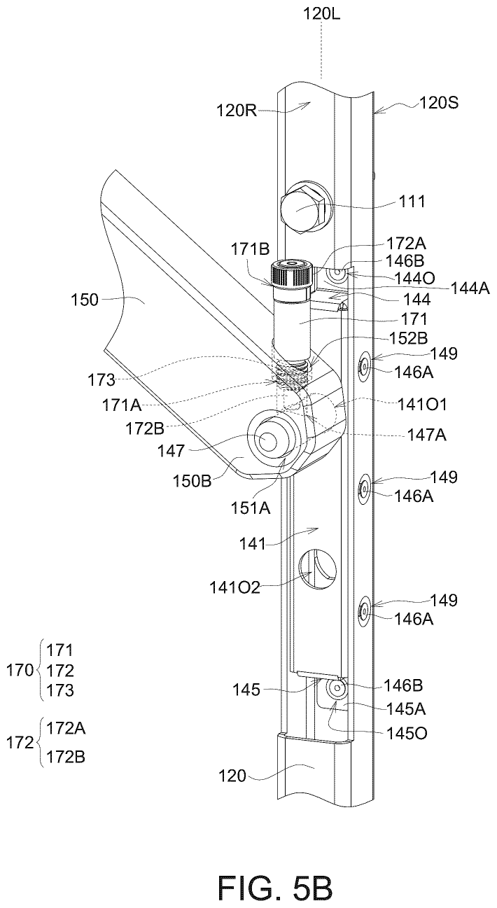

The fifth side plate 142 and the sixth side plate 143 respectively have a plurality of through holes 149, and the second adapter 140 is fixed to the inner side walls 120N on both sides of the second tubular shell structure by a plurality of fixing units (e.g., a plurality of rivets 146A) passing through the through holes 149. The seventh side plate 144 and the eighth side plate 145 respectively include a flange 144A and 145A extending away from the seventh side plate 144 and the eighth side plate 145 along a direction parallel to the second longitudinal axis 120L, and the flanges 144A and 145A respectively have a through hole 144O and 145O. The second adapter 140 is fixed to the inner bottom plate 120B of the second tubular shell structure by rivets 146B respectively passes through the through holes 144O and 145O (see FIG. 5A and FIG. 5B). The second upper plate 141 is parallel to and slightly lower in height than the second adapting surface 120R of the second support member 120, and has a second latch hole 141O1 and a third latch hole 141O2 passing the second upper plate 141.

In addition, the second adapter 140 further includes a second pole 147 and a third pole 148. One end of the second pole 147 is fixed to the inner bottom plate 140B of the second tubular shell structure, and the other end of the second pole 147 passes through the second latch hole 141O1 and extends out of the second upper plate 141 and the second opening 120O of the second support member 120. One end of the third pole 148 is fixed on the inner bottom plate 140B of the second tubular shell structure, and the other end of the third pole 148 passes through the third latch hole 141O2 and extends out of the second upper plate 141 and the second opening 120O of the second support member 120.

Refer to FIG. 1A and FIG. 1B again, the first connecting rod 150 spans between the first support member 110 and the second support member 120. The first connecting rod 150 respectively forms a first acute angle θ1 and a second acute angle θ2 with the first support member 110 and the second support member 120. The first connecting rod 150 may be a tubular shell structure, a rod-shaped structure or a long plate-shaped structure made of alloy tool steel. The first end 150A of the first connecting rod 150 has a first through hole 151A, which allows the first pole 137 of the first adapter 130 to pass therethrough. In addition, the first connecting rod 150 can be detachably connected to the first adapter 130 via the first quick-release connection component 160. The second end 150B of the first connecting rod 150 has a second through hole 151B, which allows the second pole 147 of the second adapter 140 to pass therethrough. In addition, the first connecting rod 150 can be detachably connected to the second adapter 140 via the second quick-release connection component 170.

Refer to FIG. 4A and FIG. 4B, FIG. 4A is an enlarged perspective view illustrating a partial structure in an engaged state of the first adapter 130, the first quick-release connection component 160 and the first end 150A of a first connecting rod 150, according to one embodiment of the present disclosure. FIG. 4B is an enlarged perspective view illustrating a partial structure in a disengaged state of the first adapter 130, the first quick-release connection component 160 and the first end 150A of the first connecting rod 150, as depicted based on FIG. 4A. In the present embodiment, the first end 150A of the first connecting rod 150 further includes a first side hole 152A, which is perpendicular to and connected to the first through hole 151A, and is configured to receive insertion of the first quick-release connection component 160. The second end 150B of the first connecting rod 150 further includes a second side hole 152B, which is perpendicular to and connected to the second through hole 151B, and is configured to receive insertion of the second quick-release connection component 170.

The first quick-release connection component 160 includes a first sleeve 161 and a first pin 162. The first sleeve 161 has a coupling port 161A and an exposed port 161B away from the coupling port 161A. The coupling port 161A has a thread 163 for locking the first sleeve 161 in the first side hole 152A of the first end 150A of the first connecting rod 150. The first pin 162 is movably disposed and secured within the first sleeve 161, and is selectively extendable into the first through hole 151A formed at the first end 150A of the first connecting rod 150 so as to engage the first pole 137 of the first adapter 130.

In the present embodiment, the first pin 162 has a handle portion 162A and a pin rod 162B. A portion of the handle portion 162A is disposed inside the first sleeve 161, while another portion thereof is exposed outside the exposed port 161B. One end of the pin rod 162B is connected to the handle portion 162A and the other end is inserted into the first sleeve 161. The pin rod 162B is confined in the first sleeve 161 by an elastic fixing member, such as a spring (not shown), disposed inside the first sleeve 161, and can reciprocate along a direction parallel to a longitudinal axis 161L of the first sleeve 161.

When the first adapter 130, the first quick-release connection component 160 and the first end 150A of a first connecting rod 150 are in the engaged state (as shown in FIG. 4A) , the end of the pin 162B away from the handle portion 162A extends through the coupling port 161A of the first sleeve 161, enters the first through hole 151A of the first connecting rod 150, and engages in the engaging recess 137A of the first pole 137 of the first adapter 130 that passes through the first through hole 151A. At this time, the first adapter member 130, the first quick-release connection component 160 and the first end 150A of the first connecting rod 150 are engaged with each other. Accordingly, the first connecting rod 150 can be interchangeably and detachably connected to the first support member 110.

In some embodiments of the present disclosure, the portion of the handle portion 162A disposed inside the first sleeve 161 has a groove (not shown). When the first adapter 130, the first quick-release connection component 160 and the first end 150A of the first connecting rod 150 are engaged with each other, the handle portion 162A can be rotated to engage the engagement groove (not shown) with an engagement portion (not shown) inside the first sleeve 161 to prevent displacement of the pin 162B under external force and maintain the engagement among the first adapter 130, the first quick-release connection component 160 and the first end 150A of the first connecting rod 150.

When the handle portion 162A is pulled outwardly away from the exposed port 161B (as shown in FIG. 4B) by an external force, the end of the pin 162B is driven to leave the engaging recess 137A and move to the inside of the coupling port 161A of the first sleeve 161, that is the pin 162B retracts inwardly toward the handle portion 162A. At this time, the first quick-release connection component 160 and the first end 150A of the first connecting rod 150 can be separated from each other. If the first through hole 151A of the first connecting rod 150 is further separated from the first pole 137 of the first adapter 130, the first connecting rod 150 can be quickly removed from the first support member 110.

Refer to FIG. 5A and FIG. 5B, FIG. 5A is a perspective enlarged view illustrating a partial structure in an engaged state of the second adapter 140, a second quick-release connection component 170 and a second end 150B of the first connecting rod 150 according to one embodiment of the present disclosure. FIG. 5B is a perspective enlarged view illustrating a partial structure in a disengaged state of the second adapter 140, the second quick-release connection component 170 and the second end 150B of the first connecting rod 150.

Similarly, the second quick-release connection component 170 includes a second sleeve 171 and a second pin 172. The second sleeve 171 has a coupling port 171A and an exposed port 171B away from the coupling port 171A. The coupling port 171A has a thread 173 for locking the second sleeve 171 in the second side hole 152B of the second end 150B of the first connecting rod 150. The second pin 172 has a handle portion 172A and a pin rod 172B. A portion of the handle portion 172A is disposed inside the second sleeve 171, while another portion thereof is exposed outside the exposed port 171B. One end of the pin rod 172B is connected to the handle portion 172A and the other end is inserted into the second sleeve 171. The pin rod 172B is confined in the second sleeve 171 by an elastic fixing member, such as a spring (not shown), disposed inside the second sleeve 171, and can reciprocate along a direction parallel to a longitudinal axis 171L of the second sleeve 171.

When the second adapter 140, a second quick-release connection component 170 and a second end 150B of the first connecting rod 150 are in the engaged state (as shown in FIG. 5A) , the end of the pin 172B away from the handle portion 172A extends through the coupling port 171A of the second sleeve 171, enters the second through hole 151B of the first connecting rod 150, and engages in the engaging recess 147A of the second pole 147 of the second adapter 140 inserted into the second through hole 151B. As a result, the second adapter 140, the second quick-release connection component 170 and the second end 150B of the first connecting rod 150 engage with each other. In this way, the first connecting rod 150 can be interchangeably and detachably connected to the second support member 120.

As shown in FIG. 5B, when the handle portion 172A is pulled outwardly away from the exposed port 171B by an external force, the end of the pin 172B is driven to leave the engaging recess 147A and move to the inside of the coupling port 171A of the second sleeve 171, that is, the pin 172B retracts inwardly toward the handle portion 172A. At this time, the second quick-release connection component 170 and the second end 150B of the first connecting rod 150 are separated from each other. If the second through hole 151B of the first connecting rod 150 is separated from the second pole 147 of the second adapter 140, the first connecting rod 150 can be quickly removed from the second support member 120.

In some embodiments of the present disclosure, the shelf-auxiliary structure 100 further includes a second connecting rod 180, which is detachably connected to the first support member 110 and the second support member 120 by means of a second adapter 140, a third adapter 190, a third quick-release connection component 210 and a fourth quick-release connection component 220. The second connecting rod 180 respectively forms a third acute angle θ3 and a fourth acute angle θ4 with the first support member 110 and the second support member 120.

As shown in FIG. 1, the third adapter 190 and the second adapter 140 have similar structures. Both adapters are rectangular shell structures and fixed within a third opening 113 of the first support member 110 and are positioned away from the first adapter 130 (the first opening 110O). The third adapter 190 includes a fourth pole 197, one end of the fourth pole 197 is fixed to the inner bottom plate 110B of the first tubular shell structure, and the other end of the fourth pole 197 passes through a fourth latch hole (not shown) penetrating the upper plate (not shown) of the third adapter 190 and extends out of the upper plate (not shown) of the third adapter 190 and the third opening 113 of the first support member 110.

The third quick-release connection component 210 is disposed at the third end 180A of the second connecting rod 180 and is detachably connected to the third pole 148 of the second adapter 140 (see FIG. 2B). The fourth quick-release connection component 220 is disposed at the fourth end 180B of the second connecting rod 180 and is detachably connected to the fourth pole 197 of the third adapter 190. Since the engaging and disassembly mechanisms of the third quick-release connection component 210 and the second adapter 140, and between the third adapter 190 and the fourth quick-release connection component 220, are generally similar to the engaging/disassembly method between the first quick-release connection component 160 and the first adapter 130 and/or the engaging/disassembly method between the second quick-release connection component 170 and the second adapter 140 (as shown in FIG. 5A and FIG. 5B); thus the engaging/disassembly method thereof will not redundantly described here.

In the present embodiment, since the first connecting rod 150 and the second connecting rod 180 have the same structure, thus they can be interchangeably and detachably connected to the first support member 110 and the second support member 120. In addition, in one embodiment of the present disclosure, the shelf-auxiliary structure 100 may include additional first connecting rods 150 and second connecting rods 180, which are detachably secured to the first support member 110 and the second support member 120 through the structure as described above to form a connecting structure. Thereby the outer frame 10F of the shelf structure 10 can be strengthen to provide shock absorption and vibration isolation effects.

For example, the first through hole 151A and the second through hole 151B of the first connecting rod 150 are of the same size have the same dimensions and are disposed on the same side of the first connecting rod 150, while the first side hole 152A and the second side hole 152B are of the same size but are disposed on the opposite sides relative to the longitudinal axis of the first connecting rod 150. In combination with the first quick-release connecting component 160 and the second quick-release connecting component 170 having identical structure, after the first connecting rod 150 is rotated 180 degrees, it can also be detachably fixed on the first support member 110 and the second support member 120 by using the same quick release components (the first quick-release connecting component 160 and the second quick-release connecting component 170).

In another embodiment of the present disclosure, one end of the first connecting rod 150 can be detachably fixed to the first support member 110 using the first quick-release connecting component 160, while the other end of the first connecting rod 150 can be fixed to the first support member 110 in other ways.

In addition, the shelf structure 10 may be laterally secured in an abutting arrangement with another shelf 11 by at least one bridging component 201, such that the frame 10F of the shelf structure 10 is fixed side-by-side against the frame 11F of the shelf structure 11 (e.g., by fastening with screws and nuts), and the aforementioned shelf auxiliary structure 100 is disposed on the outer frame 11F of the shelf structure 11. In the present embodiment, the second support member 120 adjacent to the outer frame 11F of the shelf structure 11 further has a join opening 124 disposed on the second connecting surface 120S facing the outer frame 10F to allow the joining element 201 to pass therethrough.

According to the above embodiments, the present disclosure provides a shelf-auxiliary structure. By fixing the first support member and the second support member on the outer frame of the shelf structure, and connecting the connecting rod between the first support member and the second support member through the first quick-release connection component, the second quick-release connection component, the first adapter and the second adapter, so that the connecting rod forms a first acute angle and a second acute angle with the first support member and the second support member respectively. Thereby, a connecting structure can be formed to strengthen the outer frame of the shelf structure to provide the effect of shock absorption and vibration prevention. In some embodiments, the number of connecting rods can be increased according to shock absorption requirements. Since the connecting rod can be assembled and disassembled by quick release mechanisms, and can be interchanged with each other, thus it not only greatly reduces the time cost for assembling and building the self-auxiliary structures, but also improves the spatial flexibility of the shelf structure. In addition, the shelf-auxiliary structure of the present disclosure is designed to be compatible with standard shelf specifications, and thus can be retrofitted to any shelf for electronic equipment, enabling shock protection without replacing the existing shelf structure.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A shelf-auxiliary structure, comprising:
a first support member, fixed to an outer frame of a shelf structure;
a second support member, fixed to the outer frame and separated from the first support member;
a first adapter, fixed on the first support member;
a second adapter, fixed on the second support member;
a first connecting rod, spanning between the first support member and the second support member, so as to form a first acute angle and a second acute angle with the first support member and the second support member respectively;
a first quick-release connection component, disposed at a first end of the first connecting rod and detachably connected to the first adapter; and
a second quick-release connection component, disposed at a second end of the first connecting rod and detachably connected to the second adapter.

2. The shelf-auxiliary structure according to claim 1, wherein the first quick-release connection component and the second quick-release connection component have the same structure.

3. The shelf-auxiliary structure according to claim 1, wherein
the first support member is a first tubular shell structure having a first connecting surface facing the outer frame and a first adapting surface opposite to the first connecting surface, and the first adapting surface has a first opening, through which the first adapter can be installed in the first tubular shell structure; and
the second support member is a second tubular shell structure having a second connecting surface facing the outer frame and a second adapting surface opposite to the second connecting surface, and the second adapting surface has a second opening, through which the second adapter can be installed in the second tubular shell structure.

4. The shelf-auxiliary structure according to claim 3, wherein
the first adapter is a rectangular shell structure having a size substantially smaller than the first opening, and has a first upper plate, a first side plate, a second side plate, a third side plate and a fourth side plate, wherein the first side plate and the second side plate are both parallel to a first longitudinal axis of the first tubular shell structure, and the third side plate and the fourth side plate are both perpendicular to the first longitudinal axis; and
the second adapter is a rectangular shell structure having a size substantially smaller than the second opening, and has a second upper plate, a fifth side plate, a sixth side plate, a seventh side plate and an eighth side plate; wherein the fifth side plate and the sixth side plate are both parallel to a second longitudinal axis of the second tubular shell structure, and the seventh side plate and the eighth side plate are both perpendicular to the second longitudinal axis.

5. The shelf-auxiliary structure according to claim 4, wherein
the first side plate and the second side plate are respectively fixed to inner side walls of the first tubular shell structure by a plurality of fixing units, the first upper plate is parallel to the first adapting surface and has a first latch hole penetrating there through; and
the fifth side plate and the sixth side plate are respectively fixed to the inner side walls of the second tubular shell structure by a plurality of fixing units, the second upper plate is parallel to the second adapting surface and has a second latch hole penetrating there through.

6. The shelf-auxiliary structure according to claim 5, wherein
the first adapter comprises a first pole, one end of the first pole is fixed to an inner bottom plate of the first tubular shell structure, and the other end of the first pole passes through the first latch hole and extends out of the first upper plate and the first opening; and
the second adapter comprises a second pole, one end of the second pole is fixed to an inner bottom plate of the second tubular shell structure, and the other end of the second pole passes through the second latch hole and extends out of the second upper plate and the second opening.

7. The shelf-auxiliary structure according to claim 6, wherein the first connecting rod further comprises:
a first through hole, disposed at the first end and allowing the first pole to pass there through, wherein the first connecting rod can be detachably connected to the first adapter via the first quick-release connection component; and
a second through hole, disposed at the second end and allowing the second pole to pass there through, wherein the first connecting rod can be detachably connected to the second adapter via the second quick-release connection component.

8. The shelf-auxiliary structure according to claim 7, wherein the first connecting rod further comprises:
a first side hole, perpendicular to and connected to the first through hole, used to receive insertion oft the first quick-release connection component ; and
a second side hole, perpendicular to and connected to the second through hole, used to receive insertion of the second quick-release connection component.

9. The shelf-auxiliary structure according to claim 8, wherein the first side hole and the second side hole are disposed on opposite sides of the first connecting rod.

10. The shelf-auxiliary structure according to claim 8, wherein
the first quick-release connection component comprises a first sleeve and a first pin, wherein the first sleeve has a thread for locking the first sleeve in the first side hole and the first pin is movably disposed and secured within the first sleeve and is selectively extendable into the first through hole to engage with the first pole; and
the second quick-release connection component comprises a second sleeve and a second pin, wherein the second sleeve has a thread for locking the second sleeve in the second side hole and the second pin is movably disposed and secured within the second sleeve and is selectively extendable into the second through hole to engage with the second pole.

11. The shelf-auxiliary structure according to claim 5, wherein
at least one of the third side plate and the fourth side plate has a first flange parallel to the first longitudinal axis and is fixed to the inner bottom plate of the first tubular shell structure by at least one fixing unit; and
at least one of the seventh side plate and the eighth side plate has a second flange parallel to the second longitudinal axis and is fixed to the inner bottom plate of the second tubular shell structure by at least one fixing unit.

12. The shelf-auxiliary structure according to claim 4, wherein the second adapter further comprises a third pole, one end of the third pole is fixed on the inner bottom plate of the second tubular shell structure, and the other end of the third pole passes through the third latch hole of the second upper plate.

13. The shelf-auxiliary structure according to claim 12, further comprising:
a third adapter, secured within the third opening of the first support member and positioned away from the first adapter, wherein the third adapter comprises a fourth pole, one end of the fourth pole is fixed on the inner bottom plate of the first tubular shell structure, and the other end of the fourth pole passes through a fourth latch hole penetrating an upper plate of the third adapter;
a second connecting rod, spanning between the first support member and the second support member to form a third acute angle and a fourth acute angle with the first support member and the second support member, respectively;
a third quick-release connection component, disposed at a third end of the second connecting rod and detachably connected to the third pole of the second adapter; and
a fourth quick-release connection component, disposed at a fourth end of the second connecting rod and detachably connected to the fourth pole of the second adapter.

14. The shelf-auxiliary structure according to claim 13, the first connecting rod and the second connecting rod can be interchangeably and detachably connected to the first support member and the second support member.

15. The shelf-auxiliary structure according to claim 3, further comprising at least one error-proofing element protruding from at least one of the first connecting surface and second connecting surface and corresponding to at least one positioning element of the outer frame.

16. The shelf-auxiliary structure according to claim 15, further comprising at least one joining element used to join the outer frame side by side with an outer frame of another shelf structure, and one of the first support member and the second support member adjacent to the outer frame the another shelf structure has a join opening disposed on the first connecting surface to allow the joining element to pass there through.
